(19) United States
(12) Patent Application Publication
(10) Pub. No.: US 2026/0180556 A1
(43) Pub. Date: Jun. 25, 2026

(54) Acoustic Wave Device and Module

(71) Applicant: Sanan Japan Technology Corporation, Tokyo (JP)

(72) Inventors: Yuki Koto, Tokyo (JP); Shinichi Shioi, Tokyo (JP)

(21) Appl. No.: 19/409,734

(22) Filed: Dec. 5, 2025

(30) Foreign Application Priority Data
Dec. 24, 2024 (JP) 2024-227447

(51) Int. Cl. H03H 9/64; H03H 9/02; H03H 9/25

(52) U.S. Cl. CPC H03H 9/6483; H03H 9/02834; H03H 9/25

(57) ABSTRACT

An acoustic wave device is disclosed, which includes a piezoelectric substrate; a first ladder-type filter formed on the piezoelectric substrate and including a first series resonator, a second series resonator, and a first parallel resonator; a first inter-series resonator wiring that electrically connects the first series resonator and the second series resonator; a first ground pad electrically connected to the first parallel resonator; and wherein the first inter-series resonator wiring is disposed in an outer edge portion of the piezoelectric substrate relative to the first parallel resonator and the first ground pad.

### CROSS-REFERENCE TO RELATED APPLICATION

The present disclosure claims priority to Japanese Patent Application No. 2024-227447 filed December 24, 2024, the contents of which are herein incorporated by reference in its entirety.

### FIELD

This application relates to the field of mobile communication devices and, more particularly, to an acoustic wave device.

### BACKGROUND

Due to recent technological advances, mobile communication terminals such as smartphones, which are representative examples, have been remarkably miniaturized and reduced in weight. In such mobile communication terminals, acoustic wave devices that can be miniaturized are employed.

With miniaturization, ensuring the power durability of acoustic wave devices has become more severe. That is, structures with better heat dissipation than conventional ones are required.

In order to improve the heat dissipation of acoustic wave devices, for example, Patent Document 1 (JP2019-4264A) discloses a technique of enhancing heat dissipation from a device chip including a piezoelectric substrate to the package substrate side by using dummy bumps.

However, in the acoustic wave device described in Patent Document 1, the heat dissipation is not sufficient.

### SUMMARY

Some examples described herein have an object of providing an acoustic wave device with improved heat dissipation and a module including the acoustic wave device.

In some examples, an acoustic wave device is provided, which comprises a piezoelectric substrate; a first ladder-type filter formed on the piezoelectric substrate and including a first series resonator, a second series resonator, and a first parallel resonator; a first inter-series resonator wiring that electrically connects the first series resonator and the second series resonator; a first ground pad electrically connected to the first parallel resonator; and wherein the first inter-series resonator wiring is disposed in an outer edge portion of the piezoelectric substrate relative to the first parallel resonator and the first ground pad.

In some examples, a communication module includes the above-mentioned acoustic wave device.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a longitudinal sectional view of an acoustic wave device 20 in Embodiment 1.

FIG. 2 is a diagram showing an example of an acoustic wave element (resonator) of the acoustic wave device 20 in Embodiment 1.

FIG. 3 is a diagram showing an example of the acoustic wave device 20 in Embodiment 1.

FIG. 4 is a top view showing the configuration of each layer of a package substrate of the acoustic wave device 20 in Embodiment 1.

FIG. 5 is a circuit diagram of the acoustic wave device 20 in Embodiment 1.

FIG. 6 is a diagram showing the transmission characteristics of the acoustic wave device 20 in Embodiment 1.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### Embodiment 1.

FIG. 1 is a longitudinal sectional view of an acoustic wave device 20 according to Embodiment 1.

As shown in FIG. 1, the acoustic wave device 20 includes a package substrate 23, external connection terminals 24, a device chip 25, electrode pads 26, bumps 27, and a sealing portion 28.

For example, the package substrate 23 is a multilayer substrate that includes a resin. In one example, the package substrate 23 is a low temperature co-fired ceramics (LTCC) multilayer substrate formed of a plurality of dielectric layers.

A plurality of external connection terminals 24 are formed on the lower surface of the package substrate 23.

A plurality of electrode pads 26 are formed on the main surface of the package substrate 23, i.e., on the mounting surface of the device chip 25. For example, the electrode pads 26 are formed of copper or an alloy containing copper. For example, the thickness of the electrode pads 26 is from 10 μm to 20 μm.

For example, the package substrate 23 includes a first layer 231, a second layer 232, and a third layer 233, and may further include additional laminated substrates. Although not shown in FIG. 1, a plurality of metal patterns are formed between the first layer 231 and the second layer 232, and are electrically connected to the electrode pads 26 via vias formed to penetrate the first layer 231. Similarly, a plurality of metal patterns are also formed between the second layer 232 and the third layer 233, and are electrically connected to the plurality of metal patterns formed between the first layer 231 and the second layer 232 via vias formed to penetrate the second layer 232.

The bumps 27 are formed on the respective upper surfaces of the electrode pads 26. For example, the bumps 27 are gold bumps. For example, the height of the bumps 27 is from 10 μm to 50 μm.

The device chip 25 is mounted on the package substrate 23 by flip-chip bonding via the bumps 27. The device chip 25 is electrically connected to the plurality of electrode pads 26 via the plurality of bumps 27.

The device chip 25 is, for example, a surface acoustic wave device chip. The device chip 25 includes a piezoelectric substrate formed of a piezoelectric material. The piezoelectric substrate is a substrate formed of a piezoelectric single crystal such as lithium tantalate, lithium niobate, or quartz.

The thickness of the piezoelectric substrate can be, for example, from 100 μm to 300 μm. According to another example, the piezoelectric substrate is a substrate formed of piezoelectric ceramics.

According to yet another example, the device chip 25 is a substrate in which the piezoelectric substrate and a support substrate are directly bonded or indirectly bonded via an intermediate layer. The support substrate is, for example, a substrate formed of sapphire, silicon, alumina, spinel, quartz, or glass. In this case, the thickness of the piezoelectric substrate can be, for example, from 0.3 μm to 5 μm.

Acoustic wave elements are formed on the piezoelectric substrate. For example, a bandpass filter including a plurality of acoustic wave elements is formed on the main surface of the device chip 25.

According to another example, a duplexer including a transmission filter and a reception filter is formed on the main surface of the device chip 25.

The transmission filter is formed so that an electric signal in a desired frequency band can pass. For example, the transmission filter is a ladder-type filter including a plurality of series resonators and a plurality of parallel resonators.

The reception filter is formed so that an electric signal in a desired frequency band can pass. For example, the reception filter is a ladder-type filter.

The sealing portion 28 is formed so as to cover the device chip 25. For example, the sealing portion 28 is formed of an insulator such as synthetic resin. For example, the sealing portion 28 is formed of metal.

When the sealing portion 28 is formed of synthetic resin, the synthetic resin is, for example, epoxy resin or polyimide. Preferably, the sealing portion 28 is formed of epoxy resin using a low-temperature curing process.

A cavity 29 is formed in a region where the package substrate 23 and the device chip 25 face each other, thereby securing a mechanical vibration space for the acoustic wave element 52.

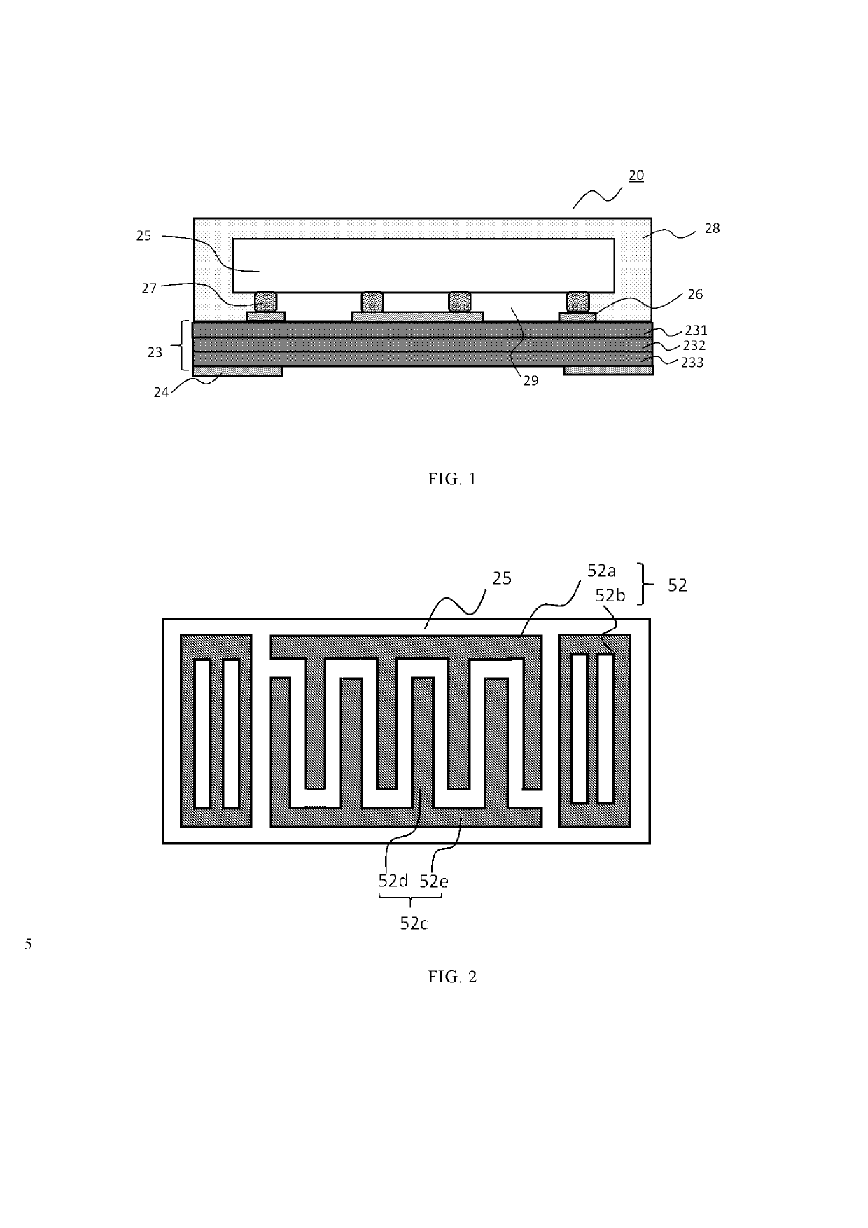

Next, an example of an acoustic wave element 52 formed on the device chip 25 will be described with reference to FIG. 2, which illustrates an example of an acoustic wave element (resonator) of the acoustic wave device 20 in Embodiment 1.

As shown in FIG. 2, an interdigital transducer (IDT) electrode 52a and a pair of reflectors 52b are formed on the main surface of the device chip 25. The IDT electrode 52a and the pair of reflectors 52b are provided so as to excite acoustic waves, primarily shear horizontal (SH) waves.

For example, the IDT electrode 52a and the pair of reflectors 52b are formed of an alloy of aluminum and copper. For example, the IDT electrode 52a and the pair of reflectors 52b are formed of an appropriate metal such as aluminum, copper, platinum, molybdenum, iridium, tungsten, cobalt, nickel, ruthenium, chromium, strontium, titanium, palladium, or silver, or an alloy thereof, or a laminated body thereof.

For example, the IDT electrode 52a and the pair of reflectors 52b are formed of a laminated metal film in which a plurality of metal layers are laminated. For example, the thickness of the IDT electrode 52a and the pair of reflectors 52b is from 150 nm to 450 nm.

The IDT electrode 52a includes a pair of comb-shaped electrodes 52c. The pair of comb-shaped electrodes 52c face each other. Each comb-shaped electrode 52c includes a plurality of electrode fingers 52d and a bus bar 52e.

The plurality of electrode fingers 52d are arranged with their longitudinal directions aligned. The bus bar 52e connects the plurality of electrode fingers 52d.

One of the pair of reflectors 52b is adjacent to one side of the IDT electrode 52a, while the other is adjacent to the opposite side thereof.

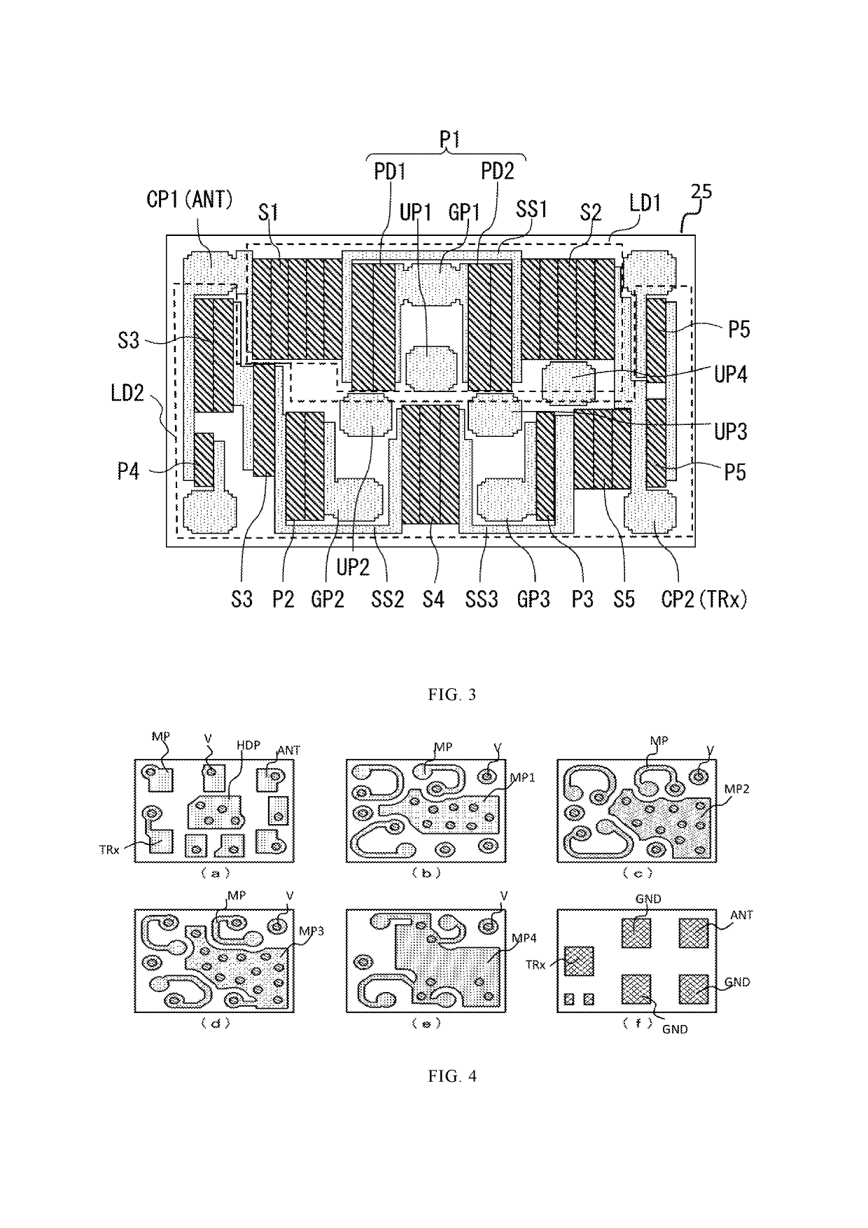

Next, with reference to FIG. 3, an example of a bandpass filter formed on the device chip 25 will be described. FIG. 3 is a diagram showing an example of the acoustic wave device 20 in Embodiment 1.

As shown in FIG. 3, a first ladder-type filter LD1, a second ladder-type filter LD2, and a plurality of pads are formed on the device chip 25. In FIG. 3, the pads are provided with reference signs indicating their circuit functions.

The first ladder-type filter LD1 includes a first series resonator S1, a second series resonator S2, a first parallel resonator P1, and a first inter-series resonator wiring SS1 that electrically connects the first series resonator S1 and the second series resonator S2.

In addition, the first parallel resonator P1 is composed of a first parallel divided resonator PD1 and a second parallel divided resonator PD2 that are connected in parallel. A first ground pad GP1 that is electrically connected to the first parallel resonator P1 is further formed. The first ground pad GP1 is formed between the first parallel divided resonator PD1 and the second parallel divided resonator PD2, and is located on the outer edge side of the device chip 25 relative to the centers of the first parallel divided resonator PD1 and the second parallel divided resonator PD2. It should be noted that each resonator may be appropriately divided in series for ensuring power durability and the like.

The first inter-series resonator wiring SS1 is formed on the outer edge side of the device chip 25 relative to the first parallel divided resonator PD1 and the first ground pad GP1.

Here, in a ladder-type filter, the wiring between series resonators tends to become high in temperature because heat generated by excitation of the two series resonators and the parallel resonator is hard to dissipate. As a result, the resonators are likely to suffer thermal destruction, making it difficult to meet power durability requirements. In particular, the farther a resonator is from a pad, the harder it is to dissipate heat and the more likely it is to suffer thermal destruction. Since the first inter-series resonator wiring SS1 is not connected to a pad, it is less likely to dissipate heat, and therefore is disposed at the outer edge to promote heat dissipation.

As a power durability measure, for example, the first series resonator S1 and the second series resonator S2 are divided in series into five. The first parallel divided resonator PD1 and the second parallel divided resonator PD2 are also each divided in series into two. Note that, in general, a parallel resonator is connected to a ground pad and is likely to dissipate heat to the package substrate 23 side through a ground bump.

The first inter-series resonator wiring SS1 is disposed on the outer edge side of the device chip 25 and is in contact with or in proximity to the sealing portion 28 that covers the device chip 25; therefore, heat is likely to be dissipated through the sealing portion 28.

Further, since the first inter-series resonator wiring SS1 is also in proximity to the first ground pad GP1, heat is likely to be dissipated to the package substrate 23 side through the first ground pad GP1. In this way, the first inter-series resonator wiring SS1 is provided with heat-dissipation paths on both sides and therefore excels in heat dissipation. As a specific example, the width of the first inter-series resonator wiring SS1 was set to 20 μm. In addition, the distance between the first inter-series resonator wiring SS1 and the first ground pad GP1 was set to 5 μm.

A first heat-dissipation floating pad UP1 is formed between the first parallel divided resonator PD1 and the second parallel divided resonator PD2, and is located closer to the center of the device chip 25 than the centers of the first parallel divided resonator PD1 and the second parallel divided resonator PD2.

The heat-dissipation floating pad is a bump pad, defined as a pad on the device chip 25 that does not contact other metal patterns. The first heat-dissipation floating pad UP1 does not contact other metal patterns on the device chip 25. In the device chip 25, the center side is less likely to dissipate heat than the outer edge side that is in contact with or in proximity to the sealing portion 28, and thus tends to become high in temperature. The first heat-dissipation floating pad UP1 is disposed on the center side of the device chip 25 and serves as a heat-dissipation path that more effectively releases heat to the package substrate 23 via bumps.

By forming the first ground pad GP1 on the outer edge side of the device chip 25 relative to the centers of the first parallel divided resonator PD1 and the second parallel divided resonator PD2, and disposing the first heat-dissipation floating pad UP1 on the center side of the device chip 25, the first inter-series resonator wiring SS1 can dissipate heat from both sides, and the center of the device chip 25 can dissipate heat via the first heat-dissipation floating pad UP1 and bumps. This provides a layout with high heat-dissipation performance that efficiently improves heat dissipation.

The second ladder-type filter LD2 includes a third series resonator S3, a fourth series resonator S4, a fifth series resonator S5, a second parallel resonator P2, a third parallel resonator P3, a fourth parallel resonator P4, and a fifth parallel resonator P5. The third series resonator S3 is divided into three series-connected segments, two of which are disposed in proximity to a common input/output pad CP1, and the remaining one is disposed via wiring. The fifth parallel resonator P5 is divided into two series-connected segments, which are vertically arranged as shown in FIG. 3.

Note that other resonators may also be appropriately divided in series for ensuring power durability and the like. The configuration further includes a second inter-series resonator wiring SS2 that electrically connects the third series resonator S3 and the fourth series resonator S4. It further includes a third inter-series resonator wiring SS3 that electrically connects the fourth series resonator S4 and the fifth series resonator S5. A second ground pad GP2 electrically connected to the second parallel resonator P2 is formed. A third ground pad GP3 electrically connected to the third parallel resonator P3 is also formed.

Preferably, the second ground pad GP2 is disposed on the outer edge side of the device chip 25 relative to the center of the second parallel resonator P2. This is because the second inter-series resonator wiring SS2, by being close to the second ground pad GP2, is likely to dissipate heat via bumps. Similarly, preferably, the third ground pad GP3 is disposed on the outer edge side of the device chip 25 relative to the center of the third parallel resonator P3. This is because the third inter-series resonator wiring SS3, by being close to the third ground pad GP3, is likely to dissipate heat via bumps.

The second inter-series resonator wiring SS2 is formed on the outer edge side of the device chip 25 relative to the second parallel resonator P2 and the second ground pad GP2. The third inter-series resonator wiring SS3 is formed on the outer edge side of the device chip 25 relative to the third parallel resonator P3 and the third ground pad GP3.

The second inter-series resonator wiring SS2 is disposed on the outer edge side of the device chip 25 and is in contact with or in proximity to the sealing portion 28 that covers the device chip 25; therefore, heat is likely to be dissipated through the sealing portion 28. Furthermore, since the second inter-series resonator wiring SS2 is also in proximity to the second ground pad GP2, heat is likely to be dissipated to the package substrate 23 side through the second ground pad GP2. In this way, the second inter-series resonator wiring SS2 is provided with heat-dissipation paths on both sides and therefore excels in heat dissipation. The same applies to the third inter-series resonator wiring SS3.

A second heat-dissipation floating pad UP2 is formed so as to be surrounded by the first parallel divided resonator PD1, the second parallel resonator P2, and the fourth series resonator S4. A third heat-dissipation floating pad UP3 is formed so as to be surrounded by the second parallel divided resonator PD2, the fourth series resonator S4, and the third parallel resonator P3. The second heat-dissipation floating pad UP2 and the third heat-dissipation floating pad UP3 are disposed on the center side of the device chip 25 relative to the center of the fourth series resonator S4.

In the device chip 25, the center side is less likely to dissipate heat than the outer edge side that is in contact with or in proximity to the sealing portion, and thus tends to become high in temperature. The second heat-dissipation floating pad UP2 and the third heat-dissipation floating pad UP3 are disposed on the center side of the device chip 25 and serve as heat-dissipation paths more effectively via bumps.

By forming the second ground pad GP2 on the outer edge side of the device chip 25 relative to the center of the second parallel resonator P2, and disposing the second heat-dissipation floating pad UP2 on the center side of the device chip 25, the second inter-series resonator wiring SS2 can dissipate heat from both sides, and the center of the device chip 25 can dissipate heat via the second heat-dissipation floating pad UP2 and bumps. This provides a layout with high heat-dissipation performance that efficiently improves heat dissipation.

Similarly for the third ground pad GP3, by forming the third ground pad GP3 on the outer edge side of the device chip 25 relative to the center of the third parallel resonator P3, and disposing the third heat-dissipation floating pad UP3 on the center side of the device chip 25, the third inter-series resonator wiring SS3 can dissipate heat from both sides, and the center of the device chip 25 can dissipate heat via the third heat-dissipation floating pad UP3 and bumps. This provides a layout with high heat-dissipation performance that efficiently improves heat dissipation.

A fourth heat-dissipation floating pad UP4 is formed so as to be surrounded by the second series resonator S2, the third parallel resonator P3, and the fifth series resonator S5. Since series resonators are not connected to ground pads, they are particularly prone to heat accumulation. Therefore, from the standpoint of improving heat dissipation, it is useful to dispose a heat-dissipation floating pad in a region sandwiched between the plurality of series resonators (i.e., the second series resonator S2 and the fifth series resonator S5).

The first ladder-type filter LD1 and the second ladder-type filter LD2 have common input/output pads CP1 and CP2, together forming a single bandpass filter. Specifically, the first ladder-type filter LD1 constitutes a high-frequency-side passband, while the second ladder-type filter LD2 constitutes a low-frequency-side passband. This is because configuring the high-frequency-side passband with a smaller number of parallel resonators reduces the requirement for low-frequency-side attenuation, thereby enabling efficient implementation of a wideband bandpass filter.

The bandpass filter constituted by the first ladder-type filter LD1 and the second ladder-type filter LD2 can have a relative bandwidth of 6% to 9%. To configure a wideband bandpass filter, a general Y-cut angle 42-degree lithium tantalate single-crystal substrate has an insufficient electromechanical coupling coefficient. Meanwhile, since Band 41 for transmission and reception requires high power handling capability, it is desirable to employ a ladder-type filter. Therefore, by adopting two ladder-type filters that constitute a high-frequency-side passband and a low-frequency-side passband, respectively, it is possible to configure a wideband bandpass filter with high power handling capability.

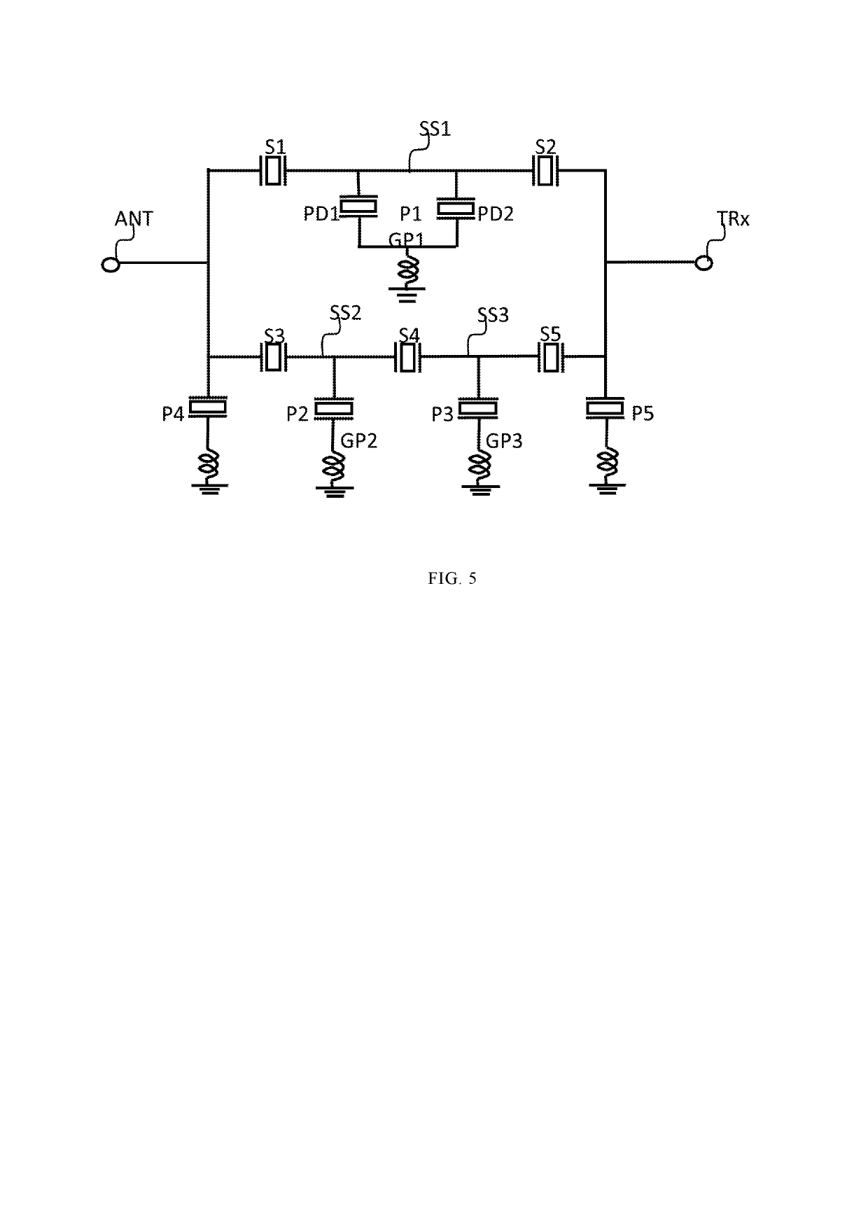

FIG. 4 is a top view showing the configuration of each layer of the package substrate 23 of the acoustic wave device 20 in Embodiment 1. FIGS. 4(b) to 4(f) are top views viewed in perspective in the vertical direction of the plane of FIG. 4(a). The vias V formed in FIGS. 4(a) to 4(e) electrically connect corresponding positions of the metal patterns in FIGS. 4(b) to 4(f). For example, the via V shown in FIG. 4(a) electrically connects the metal pattern of FIG. 4(a) and the metal pattern of FIG. 4(b). Here, the term “metal pattern MP” is defined as a concept inclusively encompassing those patterned with metal such as a heat-dissipation pad HDP, an antenna pad ANT, a transmit/receive pad TRx, pads connected to ground, and inductor patterns, which will be described later.

FIG. 4(a) illustrates the configuration of the mounting surface of the package substrate 23, where the device chip 25 is flip-chip bonded on via a plurality of bumps. As shown in FIG. 4(a), a total of nine metal patterns MP are formed on the mounting surface, including a heat-dissipation pad HDP which has the largest area among the plurality of metal patterns. The mounting surface further includes an antenna pad ANT, a transmit/receive pad TRx, and pads connected to ground.

Only the bumps bonded to the heat-dissipation floating pad are connected to the heat-dissipation pad HDP.

Since the layout of the device chip 25 shown in FIG. 3 is flip-chip bonded, for example, the common input/output pads CP1 and CP2 in FIG. 3 are flipped and bonded respectively to the antenna pad ANT and the transmit/receive pad TRx of FIG. 4(a) via bumps.

FIG. 4(b) illustrates the configuration of the metal patterns MP of a first inner layer (i.e., the first metal layer) as viewed from the mounting-surface side. A total of eight metal patterns MP are formed in the first inner layer. A first metal pattern MP1, which has the largest area among the metal patterns in the first inner layer, is formed in the first inner layer.

Referring to FIGS. 4(a) and 4(b) together, the heat-dissipation pad HDP and the first metal pattern MP1 are electrically connected by four vias V. The first metal pattern MP1 has a larger area than the heat-dissipation pad HDP. In addition, three inductor patterns are formed in the first inner layer and are electrically connected to the respective pads via the vias V.

FIG. 4(c) illustrates the configuration of the metal patterns MP of a second inner layer (i.e., the second metal layer) as viewed from the mounting-surface side. A total of seven metal patterns MP are formed in the second inner layer. A second metal pattern MP2, which has the largest area among the metal patterns in the second inner layer, is formed in the second inner layer.

Referring to FIG. 4(b) together, the second metal pattern MP2 and the first metal pattern MP1 are electrically connected by eight vias V. The second metal pattern MP2 has a larger area than the first metal pattern MP1. Three inductor patterns are also formed in the second inner layer. Each inductor pattern is electrically connected to the inductor pattern of FIG. 4(b) via the vias V.

FIG. 4(d) illustrates the configuration of the metal patterns MP of a third inner layer (i.e., the third metal layer) as viewed from the mounting-surface side. A total of six metal patterns MP are formed in the third inner layer. A third metal pattern MP3, which has the largest area among the metal patterns in the third inner layer, is formed in the third inner layer.

Referring to FIG. 4(c) together, the third metal pattern MP3 and the second metal pattern MP2 are electrically connected by ten vias V. In addition, four inductor patterns are formed in the third inner layer. Each inductor pattern is electrically connected to the inductor pattern of FIG. 4(c) via the vias V.

FIG. 4(e) illustrates the configuration of the metal patterns MP of a fourth inner layer (i.e., the fourth metal layer) as viewed from the mounting-surface side. A total of three metal patterns MP are formed in the fourth inner layer. A fourth metal pattern MP4 is formed in the fourth inner layer.

Referring to FIG. 4(d) together, the fourth metal pattern MP4 and the third metal pattern MP3 are electrically connected by fourteen vias V. The fourth metal pattern MP4 is also electrically connected to each inductor pattern of the third inner layer via the vias V.

FIG. 4(f) illustrates the configuration of the external connection terminals 24 of the package substrate 23. The external connection terminals include a transmit/receive terminal TRx, an antenna terminal ANT, and ground terminals GND.

Here, the heat-dissipation pad HDP, the first metal pattern MP1, the second metal pattern MP2, and the third metal pattern MP3 constitute a configuration that becomes the ground potential of the acoustic wave device only after being electrically connected to the metal patterns MP of the third inner layer or the fourth inner layer; until then, they are constituted only by large metal patterns. The inventors have found that a package substrate 23 with high heat-dissipation performance can be configured by using, in the lamination direction, a plurality of large metal patterns in combination from the bumps bonded to the heat-dissipation floating pad without passing through inductor patterns, wiring patterns, and the like.

To secure ground inductance in a ladder-type filter, it is common to form inductor patterns on the package substrate 23. However, these inductor patterns occupy regions with small metal pattern areas and few vias, resulting in poor heat dissipation. In addition, heat tends to accumulate in the central region of the device chip.

Accordingly, it has been found that heat dissipation is improved by providing, in the central region of the device chip, a heat-dissipation floating pad and bumps bonded to the heat-dissipation floating pad, disposing on the package substrate side a large-area metal pattern as the heat-dissipation pad HDP, and using, in the lamination direction, a plurality of large metal patterns in combination without passing through inductor patterns and the like.

Furthermore, focusing on the fact that heat diffuses radially, a configuration in accordance with the natural law of heat diffusion was adopted by making the area of the first metal pattern MP1 larger than the area of the heat-dissipation pad HDP, and making the area of the second metal pattern MP2 larger than the area of the first metal pattern MP1.

For the same reason, it is desirable to adopt a configuration in accordance with the natural law of heat diffusion by increasing the number of vias connecting the first metal pattern MP1 and the second metal pattern MP2 relative to the number of vias connecting the heat-dissipation pad HDP and the first metal pattern MP1.

FIG. 5 illustrates the circuit diagram of the acoustic wave device 20 in Embodiment 1. As shown in FIG. 5, the acoustic wave device 20 in Embodiment 1 comprises a first ladder-type filter LD1 including a first series resonator S1, a second series resonator S2, and a first parallel resonator P1, and a second ladder-type filter LD2 including a third series resonator S3, a fourth series resonator S4, a fifth series resonator S5, a second parallel resonator P2, and a third parallel resonator P3.

The first series resonator S1 was configured such that five divided resonators connected in series were used, each having an aperture length of 17.01λ, a number of electrode finger pairs of 135.5, and a resonator capacitance of 1.50 pF. The second series resonator S2 was configured such that five divided resonators connected in series were used, each having an aperture length of 17.01λ, a number of electrode finger pairs of 132.5, and a resonator capacitance of 1.45 pF. The third series resonator S3 was configured such that three divided resonators connected in series were used, each having an aperture length of 17.41λ, a number of electrode finger pairs of 158.0, and a resonator capacitance of 1.86 pF. The fourth series resonator S4 was configured such that three divided resonators connected in series were used, each having an aperture length of 17.48λ, a number of electrode finger pairs of 168.5, and a resonator capacitance of 1.98 pF. The fifth series resonator S5 was configured such that three divided resonators connected in series were used, each having an aperture length of 17.50λ, a number of electrode finger pairs of 100.0, and a resonator capacitance of 1.20 pF. The first parallel resonator P1 was configured such that a first parallel divided resonator PD1 and a second parallel divided resonator PD2, in each of which two resonators having an aperture length of 20.88λ, a number of electrode finger pairs of 179.0, and a resonator capacitance of 2.54 pF were connected in series, were connected in parallel. The second parallel resonator P2 was configured such that two divided resonators connected in series were used, each having an aperture length of 17.56λ, a number of electrode finger pairs of 139.0, and a resonator capacitance of 1.74 pF. The third parallel resonator P3 had an aperture length of 20.36λ, a number of electrode finger pairs of 147.5, and a resonator capacitance of 2.09 pF.

The second ladder-type filter LD2 includes a fifth parallel resonator P5 disposed on the transmit/receive terminal TRx side, and a fourth parallel resonator P4 disposed on the antenna terminal ANT side.

The fourth parallel resonator P4 had an aperture length of 17.83λ, a number of electrode finger pairs of 61.0, and a resonator capacitance of 0.78 pF. The fifth parallel resonator P5 was configured such that two divided resonators connected in series were used, each having an aperture length of 17.95λ, a number of electrode finger pairs of 106.5, and a resonator capacitance of 1.38 pF.

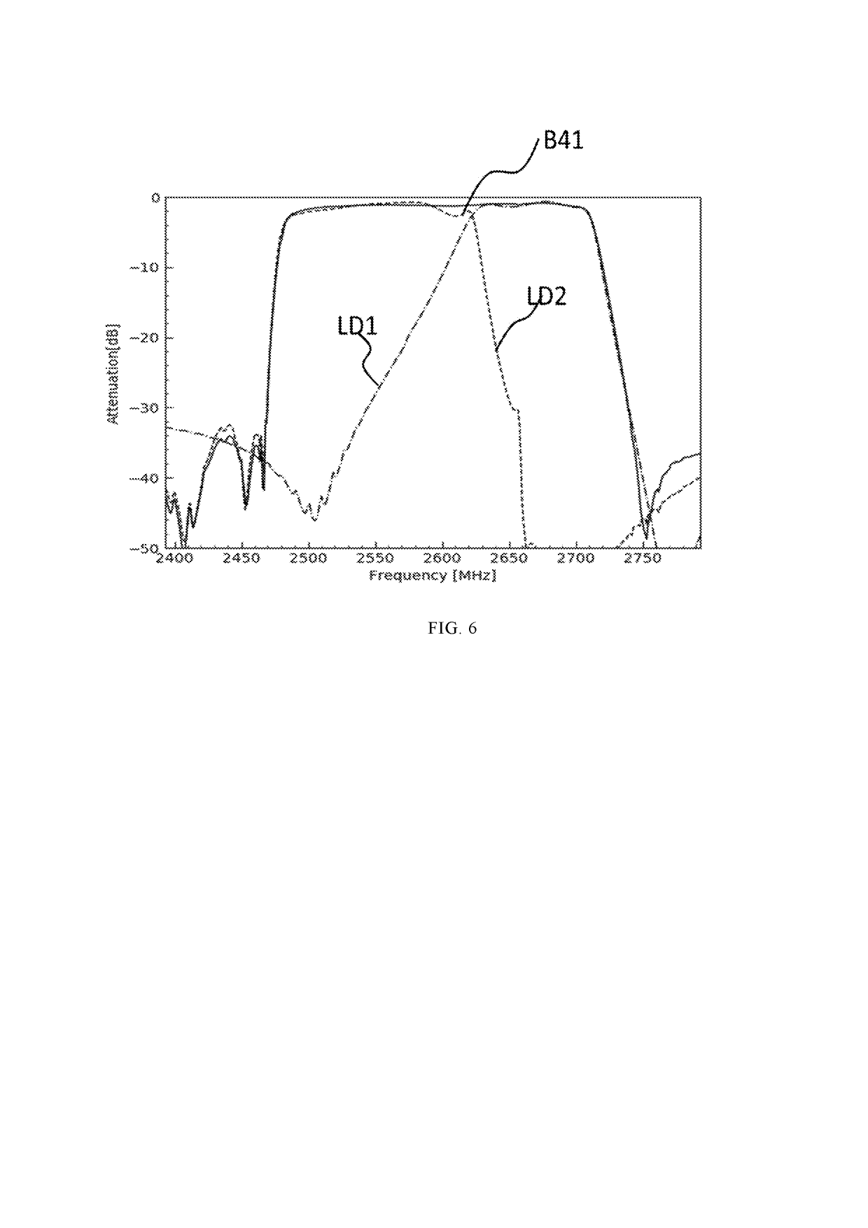

FIG. 6 illustrates the transmission characteristics of the acoustic wave device 20 in Embodiment 1. As shown in FIG. 6, the acoustic wave device 20 in Embodiment 1 realizes the transmit/receive filter for the wideband Band 41. Band 41 has a passband from 2496 MHz to 2690 MHz and a relative bandwidth of 7.48%. Since it is used for transmission and reception, high power handling is required, and therefore a ladder-type filter was adopted.

To realize a wideband bandpass filter, the passband indicated by the solid line B41 was achieved by combining a ladder-type filter, indicated by the one-dot chain line LD1, that constitutes the high-frequency-side passband, with a ladder-type filter, indicated by the broken line LD2, that constitutes the low-frequency-side passband.

At the initial stage of development, merely configuring with ladder-type filters did not achieve the high power handling required for a transmit/receive bandpass filter, but the layout of the device chip 25 in Embodiment 1 improved heat dissipation, resulting in a 0.3 dB improvement in power handling, thereby enabling provision of the acoustic wave device 20 that meets power handling requirements. Moreover, by using a package substrate with improved heat dissipation, it was possible to provide an acoustic wave device 20 with further improved heat dissipation and power handling.

While certain aspects of at least one embodiment have been described, it should be understood that various alterations, modifications, and improvements will readily occur to those skilled in the art. Such alterations, modifications, and improvements are intended to be part of the present invention and are intended to be within the scope of the present invention.

It should be understood that the embodiments of the methods and apparatus described herein are not limited to application to the details of construction and the arrangement of components set forth in the above description or illustrated in the accompanying drawings. The methods and apparatus may be implemented in other embodiments and may be practiced or carried out in various ways.

Specific implementation examples are provided herein for purposes of illustration only and are not intended to be limiting.

The expressions and terms used in the present invention are for purposes of description and should not be construed as limiting. The use of “comprising,” “including,” “having,” “containing,” and variations thereof herein shall mean inclusion of the items listed thereafter and equivalents thereof as well as additional items.

A reference to “or” (or “and/or”) is to be interpreted such that any of the terms described using “or” may indicate one, more than one, or all of the terms recited.

References to front/back/left/right, top/bottom/up/down, lateral/longitudinal, and obverse/reverse are intended for convenience of description only. Such references do not limit any component of the present invention to any one positional or spatial orientation. Accordingly, the above description and the drawings are merely illustrative.

What is claimed is:

1. An acoustic wave device, comprising:
a piezoelectric substrate;
a first ladder-type filter formed on the piezoelectric substrate and including a first series resonator, a second series resonator, and a first parallel resonator;
a first inter-series resonator wiring that electrically connects the first series resonator and the second series resonator;
a first ground pad electrically connected to the first parallel resonator; and
wherein the first inter-series resonator wiring is disposed in an outer edge portion of the piezoelectric substrate relative to the first parallel resonator and the first ground pad.

2. The acoustic wave device according to claim 1, wherein the first parallel resonator includes a first parallel divided resonator and a second parallel divided resonator connected in parallel, and the first ground pad is disposed between the first parallel divided resonator and the second parallel divided resonator.

3. The acoustic wave device according to claim 2, wherein the first ground pad is disposed closer to the outer edge side of the piezoelectric substrate than to the center of the first parallel resonator.

4. The acoustic wave device according to claim 2, further comprising a first heat-dissipation floating pad disposed between the first parallel divided resonator and the second parallel divided resonator, on the center side of the piezoelectric substrate relative to the center of the first parallel resonator.

5. The acoustic wave device according to claim 1, further comprising a second ladder-type filter including:
a third series resonator, a fourth series resonator, and a second parallel resonator formed on the piezoelectric substrate;
a second ground pad electrically connected to the second parallel resonator; and
a second inter-series resonator wiring that electrically connects the third series resonator and the fourth series resonator;
wherein the second inter-series resonator wiring is disposed in an outer edge portion of the piezoelectric substrate relative to the second parallel resonator and the second ground pad.

6. The acoustic wave device according to claim 5, wherein the second ladder-type filter further includes:
a fifth series resonator and a third parallel resonator;
a third ground pad electrically connected to the third parallel resonator; and
a third inter-series resonator wiring that electrically connects the fourth series resonator and the fifth series resonator;
wherein the third inter-series resonator wiring is disposed in an outer edge portion of the piezoelectric substrate relative to the third parallel resonator and the third ground pad.

7. The acoustic wave device according to claim 6, wherein the fourth series resonator is disposed so as to be interposed between the second ground pad and the third ground pad, and the second ground pad and the third ground pad are disposed in an outer edge portion of the piezoelectric substrate relative to the center of the fourth series resonator.

8. The acoustic wave device according to claim 7, further comprising a second heat-dissipation floating pad formed between the first parallel divided resonator and the second ground pad, wherein the second heat-dissipation floating pad is disposed on the center side of the piezoelectric substrate relative to the center of the fourth series resonator.

9. The acoustic wave device according to claim 7, further comprising a third heat-dissipation floating pad formed between the second parallel divided resonator and the third ground pad, wherein the third heat-dissipation floating pad is disposed on the center side of the piezoelectric substrate relative to the center of the fourth series resonator.

10. The acoustic wave device according to claim 5, wherein the first ladder-type filter and the second ladder-type filter share a common input/output pad and constitute a single bandpass filter.

11. The acoustic wave device according to claim 10, wherein the single bandpass filter has a relative bandwidth of 6% to 9%.

12. The acoustic wave device according to claim 10, wherein in the single bandpass filter, the first ladder-type filter constitutes a high-frequency-side passband, and the second ladder-type filter constitutes a low-frequency-side passband.

13. The acoustic wave device according to claim 1, further comprising a heat-dissipation floating pad which is disposed in a region sandwiched between the plurality of series resonators.

14. The acoustic wave device according to claim 1, wherein the first inter-series resonator wiring SS1 is also in proximity to the first ground pad.

15. The acoustic wave device according to claim 1, further comprising a package substrate and a sealing portion that seals the piezoelectric substrate together with the package substrate.

16. The acoustic wave device according to claim 15, wherein the first inter-series resonator wiring is in contact with or in proximity to the sealing portion.

17. The acoustic wave device according to claim 15, wherein the package substrate has a mounting surface with a plurality of metal patterns including a heat-dissipation pad.

18. The acoustic wave device according to claim 17, wherein the heat-dissipation pad has the largest area among the plurality of metal patterns.

19. The acoustic wave device according to claim 18, further comprising a heat-dissipation floating pad and a plurality of bumps, wherein only the bumps bonded to the heat-dissipation floating pad are connected to the heat-dissipation pad.

20. A module, comprising an acoustic wave device according to claim 1.
